(19) United States
(12) Patent Application Publication
(10) Pub. No.: US 2026/0214980 A1
(43) Pub. Date: Jul. 23, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Chun-Da LIAO, Taipei City (TW); Kai-Chieh YANG, New Taipei City (TW); Hsin-Yi LEE, Hsinchu City (TW); Hsien-Ming LEE, Changhua County (TW)

(73) Assignee: TAIWAN SEMICONDUCTOR MANUFACTURING COMPANY, LTD., Hsinchu (TW)

(21) Appl. No.: 19/034,174

(22) Filed: Jan. 22, 2025

(51) Int. Cl. H10D 84/85; H10D 30/00; H10D 30/01; H10D 30/43; H10D 62/10; H10D 64/01; H10D 64/66; H10D 84/01

(52) U.S. Cl. CPC H10D 84/851; H10D 30/014; H10D 30/0191; H10D 30/43; H10D 30/502; H10D 62/121; H10D 64/017; H10D 64/669; H10D 84/0179

(57) ABSTRACT

A method of forming a semiconductor device comprises the following steps. A first semiconductor nanostructure is formed over a substrate. A second semiconductor nanostructure is formed over the first semiconductor nanostructure. A gate dielectric layer is formed surrounding the first semiconductor nanostructure. A gate electrode is formed over the gate dielectric layer. Forming the gate electrode comprises forming a conductive liner over the gate dielectric layer and forming conductive nanoparticles over the conductive liner.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIG. 2A includes a cross-sectional view the same as the cross-sectional view along line A-A of FIG. 1.

FIG. 2B includes a cross-sectional view the same as the cross-sectional view along line B-B of FIG. 1.

FIG. 3A includes a cross-sectional view the same as the cross-sectional view along line A-A of FIG. 1.

FIG. 3B includes a cross-sectional view the same as the cross-sectional view along line B-B of FIG. 1.

FIG. 3C is a perspective view of a semiconductor device in accordance with some embodiments of the present disclosure.

FIGS. 4A, 5A and 6A include cross-sectional views the same as the cross-sectional view along line A-A of FIG. 1.

FIGS. 4B, 5B, 6B, 7 and 8A include cross-sectional views the same as the cross-sectional view along line B-B of FIG. 1.

FIGS. 8B and 8C are enlarged views of the regions in FIG. 8A.

FIG. 10A includes a cross-sectional view the same as the cross-sectional view along line A-A of FIG. 1.

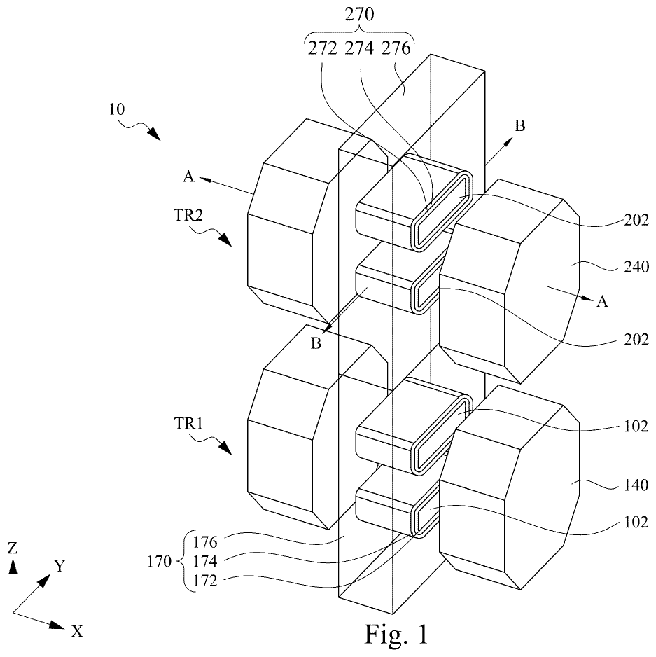

FIGS. 9, 10B, 11, 12, and 13 include cross-sectional views the same as the cross-sectional view along line B-B of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

FIG. 1 is a perspective view of a semiconductor device in accordance with some embodiments of the present disclosure. In the present disclosure, a complementary FET (CFET) structure 10 is provided, and its manufacturing method will be disclosed in the following discussion. In a CFET 10, a first transistor TR1 (a lower nanostructure field-effect transistor (nanostructure-FET)) is disposed over a substrate (not shown), and a second transistor TR2 (an upper nanostructure-FET) is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FET. The first transistor TR1 includes semiconductor layers 102 (also referred to as first semiconductor channel layers) vertically stacked one above another, a first metal gate structure 170 wrapping around each of the semiconductor layers 102, and lower source/drain epitaxy structures 140 on opposite ends of each of the semiconductor layers 102. Similarly, the second transistor TR2 includes semiconductor layers 102 (also referred to as second semiconductor channel layers) vertically stacked one above another, a second metal gate structure 270 wrapping around each of the semiconductor layers 202, and second source/drain epitaxy structures 240 on opposite ends of each of the semiconductor channel layers. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, the first transistor TR1 has a first conductivity type (e.g., n-type) and the second transistor TR2 has a second conductivity type (e.g., p-type) different from the first conductivity type. In some embodiments, the first transistor TR1 can be referred to as an N-FET, and the second transistor TR2 can be referred to as a P-FET. In some embodiments, the semiconductor layers 102 may include material suitable for N-type device, such as silicon (Si), while the second semiconductor layers 202 may include material suitable for P-type device, such as silicon germanium (SiGe).

To further improve a performance of a semiconductor device, a work function of metal gate stack of the semiconductor device may be adjusted. The adjustment may be performed by depositing several work function metal layers having different materials. The work function metal layers may be used to tune a work function of its corresponding FinFET to achieve a desired threshold voltage (Vₜ). As the device sizes shrink, tuning the sizes of the work function metal layers may become difficult.

Some embodiments of the present disclosure provide a method of forming work function metal layers by inserting conductive nanoparticles in the work function metal layers. Therefore, the work function can be tuned by controlling the coverage rate and the insertion position of the conductive nanoparticles and the thermal treatment performed to the conductive nanoparticles. Therefore, a desired threshold voltage can be tuned effectively.

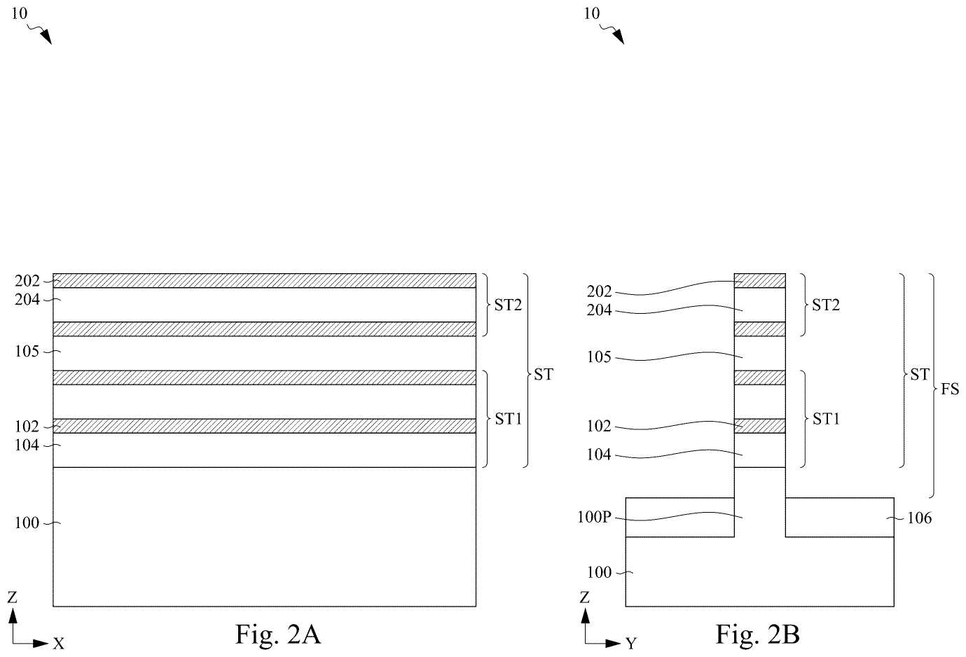

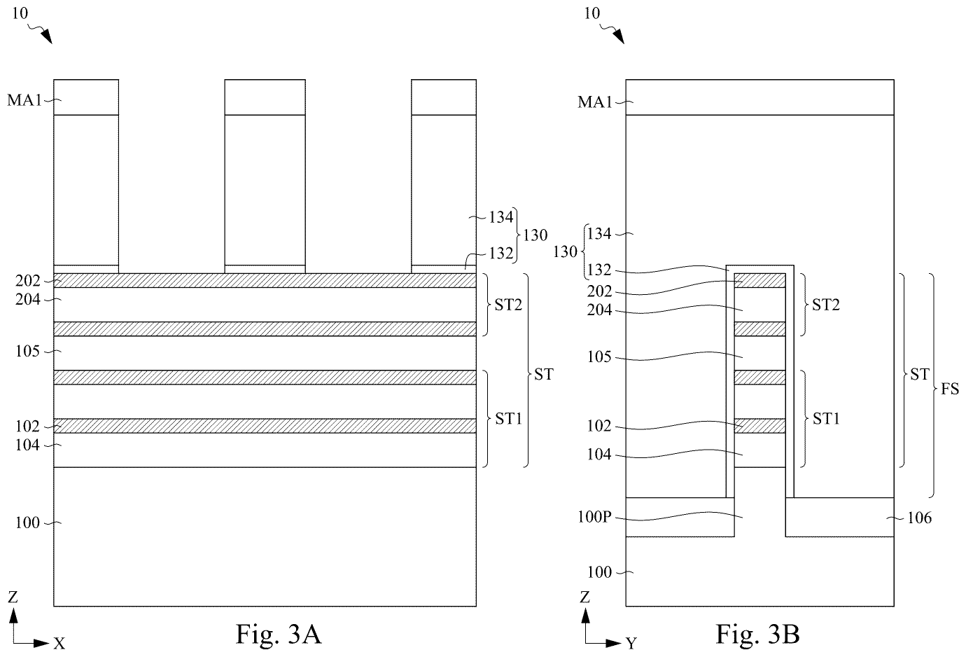

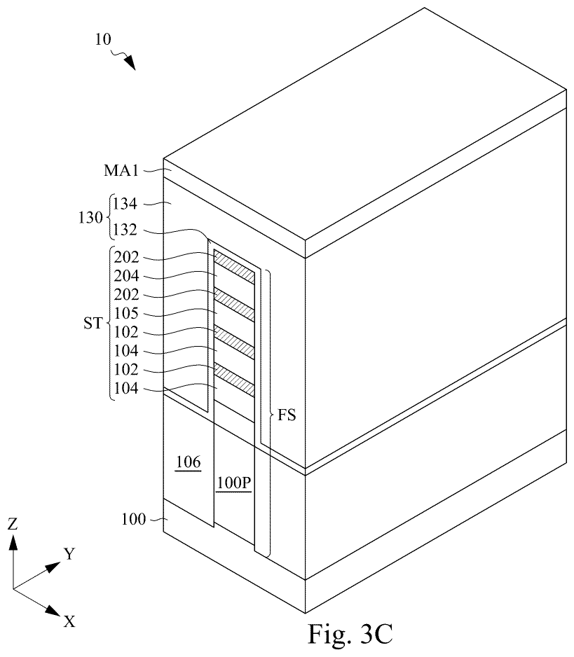

FIGS. 2A to 13 illustrate a method in various stages of forming a semiconductor device in accordance with some embodiments of the present disclosure. In greater detail, FIGS. 2A to 13 illustrate a method for forming a detailed structure of the CFET 10 of FIG. 1. It is noted that FIGS. 2A, 3A, 4A, 5A, 6A, and 10A include cross-sectional views the same as the cross-sectional view along line A-A of FIG. 1, and FIGS. 2B, 3B, 4B, 5B, 6B, 7, 8A, 9, 10B, 11, 12, and 13 include cross-sectional views the same as the cross-sectional view along line B-B of FIG. 1. FIG. 3C is a perspective view of a semiconductor device (the CFET 10) in accordance with some embodiments of the present disclosure. Although FIGS. 2A to 13 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 13 may be similar to those described with respect to FIG. 1, and thus relevant details will not be repeated for brevity. In FIGS. 2A to 13, the “A” figures (e.g., FIG. 2A) illustrate a cross-sectional view along X-direction corresponding the lines A-A illustrated in FIG. 1, and the “B” figures (e.g., FIG. 2B) illustrate a cross-sectional view along Y-direction corresponding the lines B-B illustrated in FIG. 1. Z-direction can be substantially perpendicular to the X-direction and the Y-direction and can be a vertical direction perpendicular to the substrate 100.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O3, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. The semiconductor layers 104, 204 may be removed in a subsequent process and thus may be referred to as sacrificial layers 104, 204, respectively. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 50 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es).

A patterning process may be performed to the semiconductor stack ST and the substrate 100 to form a fin structure FS, as shown in FIG. 2B. In some embodiments, the patterning process may include forming a patterned photoresist layer over the stack ST, and then performing an etching process to remove unwanted portions of the semiconductor stack ST and the substrate 100 exposed by the patterned photoresist layer. The fin structure FS may include a remaining portion of the semiconductor stack ST and a semiconductor strip 100P protruding over the substrate 100. In some embodiments, the etching process may include wet etch, dry etch, or the like.

After the fin structure FS is formed, isolation structures 106 are formed over the substrate 100 and laterally surrounding the fin structure FS. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

Reference is made to FIGS. 3A-3C. Dummy gate structures 130 are formed over the substrate 100 and crossing the fin structure FS. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask and a second hard mask over the first hard mask (not separately illustrated). The first hard mask and the second hard mask may be made of different materials. In some embodiments, the first hard mask may be formed of silicon nitride, and the second hard mask may be formed of silicon oxide.

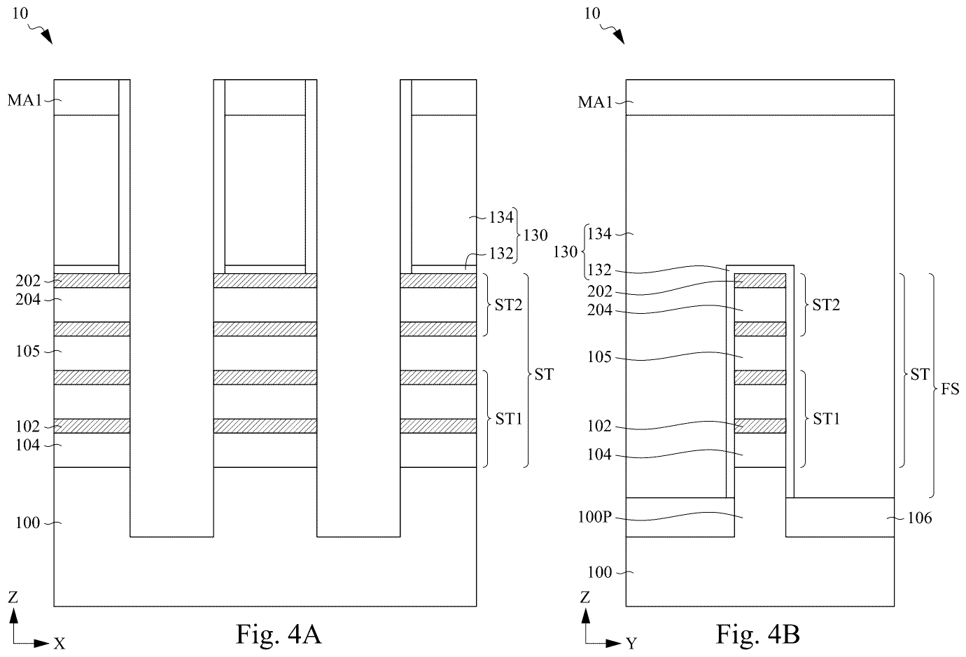

In FIGS. 4A and 4B, gate spacers 115 are formed on opposite sidewalls of each of the dummy gate structures 130. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130. In some embodiments, the remaining vertical portions of the spacer layer on sidewalls of the dummy gate structures 130 can be referred to as gate spacers 115. In some embodiments, the spacer layer may be deposited using techniques such CVD, ALD, or the like.

In FIGS. 4A and 4B, source/drain recesses R1 are formed in fin structure FS. Epitaxial source/drain regions will be subsequently formed in the source/drain recesses R1. The source/drain recesses R1 may extend through the semiconductor multilayer stack ST and into the substrate 100. The source/drain recesses R1 may be formed by etching the semiconductor multilayer stack ST and the substrate 100 using anisotropic etching processes, such as RIE, NBE, or the like. The gate spacers 115 and pattered masks MA mask portions of the semiconductor multilayer stack ST during the etching processes used to form the source/drain recesses R1. A single etch process or multiple etch processes may be used to etch each layer of the semiconductor multilayer stack ST. Timed etch processes may be used to stop the etching of the source/drain recesses R1 after the source/drain recesses R1 reach a target depth.

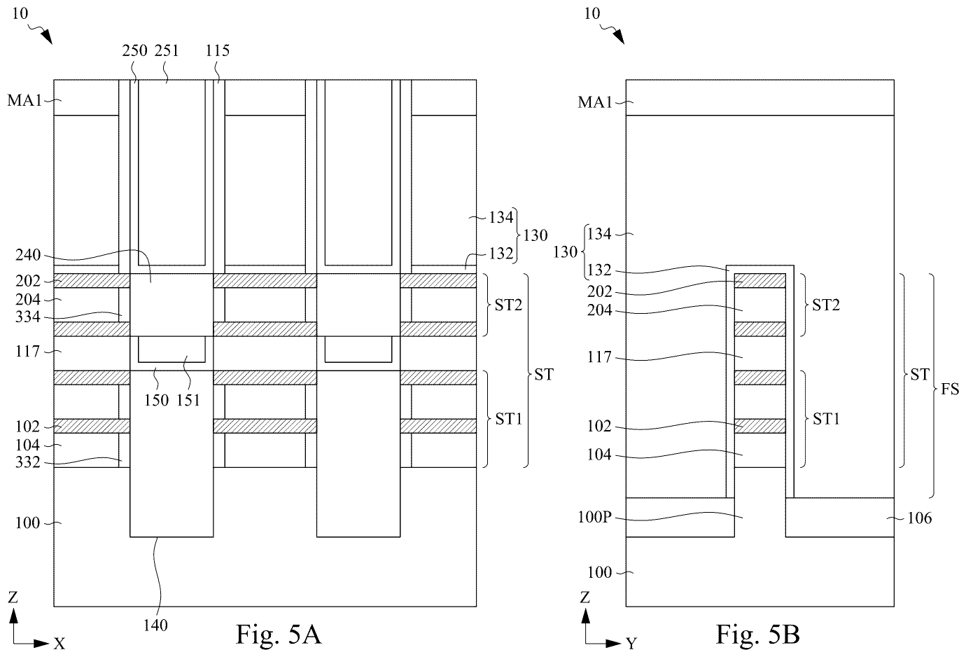

In FIGS. 5A-5B, bottom inner spacers 332, top inner spacers 334, and dielectric isolation layers 117 are formed. The formation of the bottom inner spacers 332, the top inner spacers 334 and the dielectric isolation layers 117 may include an etching process that laterally etches the semiconductor layers 104, 204 and removes the semiconductor layer 105.

The etching process may be isotropic and may be selective to the material of the semiconductor layers 104, 204, so that the semiconductor layers 104, 204 are etched at a faster rate than the semiconductor layers 102, 202. The etching process may also be selective to the material of the semiconductor layer 105, so that the semiconductor layer 105 is etched at a faster rate than the semiconductor layers 102, 202. In this manner, the semiconductor layer 105 may be completely removed from between the semiconductor layers 102 (collectively) and the semiconductor layers 202 (collectively) without completely removing the semiconductor layers 104, 204.

In some embodiments where the semiconductor layer 105 is formed of germanium or silicon germanium with a high germanium atomic percentage, the semiconductor layers 104, 204 are formed of silicon germanium with a low germanium atomic percentage, and the semiconductor layers 102, 202 are formed of silicon free from germanium, the etch process may comprise a dry etch process using chlorine gas, with or without a plasma. Because the dummy gate structures 130 warp around sidewalls of the semiconductor layers 102, 202 (see FIG. 3C), the dummy gate structures 130 may support the semiconductor layers 102, 202 so that the semiconductor layers 102, 202 do not collapse upon removal of the dummy gate structures 130. Further, although sidewalls of the dummy gate structures 130 are illustrated as being straight after the etching, the sidewalls may be concave or convex.

Bottom inner spacers 332 are formed on sidewalls of the recessed semiconductor layers 104, top inner spacers 334 are formed on sidewalls of the recessed semiconductor layers 204 and dielectric isolation layers 117 are formed between the semiconductor layers 202 (collectively) and the semiconductor layers 102 (collectively). In the subsequent formation of source/drain regions, the top and bottom inner spacers 334, 332 may act as isolation features between the subsequently formed source/drain regions and the subsequently formed gate structures. Further, the top and bottom inner spacers 334, 332 may be used to prevent damage to the subsequently formed source/drain regions by subsequent etch processes, such as the etch processes used to form gate structures. Dielectric isolation layers 117, on the other hand, are used to isolate the semiconductor layers 202 (collectively) from the semiconductor layers 102 (collectively). Furthermore, the dielectric isolation layers 117 may define the boundaries of the lower nanostructure-FETs and the upper nanostructure-FETs.

The top and bottom inner spacers 332, 334 and the dielectric isolation layers 117 may be formed by conformally depositing an insulating material in the source/drain recesses R1, and between the semiconductor layers 102, 202, and then etching the insulating material. The insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic. The insulating material, when etched, has portions remaining in the sidewalls of the semiconductor layers 104, 204 (thus forming the top and bottom inner spacers 332,334) and has portions remaining in between the semiconductor layers 102, 202 (thus forming the dielectric isolation layers 117).

As also illustrated by FIGS. 5A-5B, lower epitaxial source/drain regions 140 and upper epitaxial source/drain regions 240 are formed. The lower epitaxial source/drain regions 140 are formed in the lower portions of the source/drain recesses R1. The lower epitaxial source/drain regions 140 are in contact with the semiconductor layers 102 and are not in contact with the semiconductor layers 202. The bottom inner spacers 332 electrically insulate the lower epitaxial source/drain regions 140 from the semiconductor layers 104, which will be replaced with replacement gates in subsequent processes.

The lower epitaxial source/drain regions 140 are epitaxially grown, and have a conductivity type that is suitable for the device type (p-type or n-type) of the lower nanostructure-FETs. When the lower epitaxial source/drain regions 140 are n-type source/drain regions, the respective material may include silicon or carbon-doped silicon, which is doped with an n-type dopant such as phosphorous, arsenic, or the like. When the lower epitaxial source/drain regions 140 are p-type source/drain regions, the respective material may include silicon or silicon germanium, which is doped with a p-type dopant such as boron, indium, or the like.

The lower epitaxial source/drain regions 140 may be in-situ doped, and may be, or may not be, implanted with the corresponding p-type or n-type dopants. During the epitaxy of the lower epitaxial source/drain regions 140, the may be masked to prevent undesired epitaxial growth on the semiconductor layers 202. After the lower epitaxial source/drain regions 140 are grown, the masks on the semiconductor layers 202 may then be removed.

A first Contact Etch Stop Layer (CESL) 150 and a first Inter-Layer Dielectric (ILD) 151 are formed over the lower epitaxial source/drain regions 140. The first CESL 150 may be formed of a dielectric material having a high etching selectivity from the etching of the first ILD 151, such as silicon nitride, silicon oxide, silicon oxynitride, or the like, which may be formed by any suitable deposition process, such as CVD, ALD, or the like. The first ILD 151 may be formed of a dielectric material, which may be deposited by any suitable method, such as CVD, plasma-enhanced CVD (PECVD), or FCVD. The applicable dielectric material of the first ILD 151 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 151, followed by a planarization process and then an etch-back process. In some embodiments, the first ILD 151 is etched first, leaving the first CESL 150 unetched. An anisotropic etching process is then performed to remove the portions of the first CESL 150 higher than the recessed first ILD 151. After the recessing, the sidewalls of the semiconductor layers 202 are exposed.

Upper epitaxial source/drain regions 240 are then formed in the upper portions of the source/drain recesses R1. The upper epitaxial source/drain regions 240 may be epitaxially grown from exposed surfaces of the semiconductor layers 202. The materials of upper epitaxial source/drain regions 240 may be selected from the same candidate group of materials for forming lower source/drain regions 140, depending on the desired conductivity type of upper epitaxial source/drain regions 240.

The conductivity type of the upper epitaxial source/drain regions 240 may be opposite the conductivity type of the lower epitaxial source/drain regions 140. For example, the upper epitaxial source/drain regions 240 may be oppositely doped from the lower epitaxial source/drain regions 140. The upper epitaxial source/drain regions 240 may be in-situ doped, and/or may be implanted, with an n-type or p-type dopant. Adjacent upper source/drain regions 240 may remain separated after the epitaxy process or may be merged.

After the upper epitaxial source/drain regions 240 are formed, a second CESL 250 and a second ILD 251 are formed. The materials and the formation methods may be similar to the materials and the formation methods of first CESL 150 and first ILD 151, respectively, and are not discussed in detail herein. The formation process may include depositing the layers for second CESL 250 and second ILD 251, and performing a planarization process to remove the excess portion of the corresponding layers. After the planarization process, top surfaces of the second ILD 251, the gate spacers 115, and the dummy gate structures 130 are coplanar (within process variations). The planarization process may remove masks MA1, or leave masks MA1 unremoved.

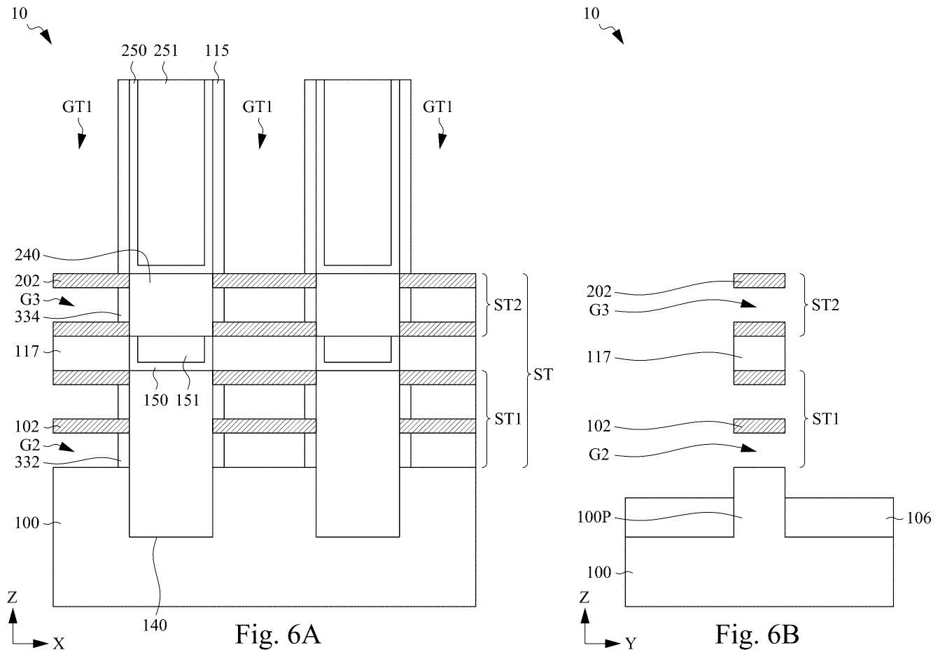

In FIGS. 6A and 6B, the dummy gate structures 130, and the patterned masks MA1 if present, are removed in one or more etching steps, so that gate trenches GT1 are formed between corresponding gate spacers 115. In some embodiments, the dummy gate structures 130 are removed by an anisotropic dry etch process. For example, the etching process may include a dry etch process using reaction gas(es) that selectively etch the dummy gate structures 130 at a faster rate than the gate spacers 115. Each gate trench GT1 exposes and/or overlies portions of semiconductor layers 102, 202, which will serve as channel regions in subsequently completed GAA-FETs. The semiconductor layers 102 serving as channel regions are disposed between neighboring pairs of the lower epitaxial source/drain regions 140. The semiconductor layers 202 serving as channel regions are disposed between neighboring pairs of the top epitaxial source/drain regions 240.

Afterwards, the semiconductor layers 104 and 204 exposed in the gate trenches GT1 are removed by an isotropic etching process such as wet etching or the like using etchants which are selective to the materials of the semiconductor layers 104 and 204. Stated differently, the semiconductor layers 104 and 204 are removed by using a selective etching process that etches the semiconductor layers 104 and 204 at a faster etch rate than it etches the semiconductor layers 102 and 202, thus forming spaces G2, G3 between corresponding two of the semiconductor layers 102 and 202, respectively, (also referred to as sheet-to-sheet spaces, because the semiconductor layers 102 and 202 are also called nanosheets). This step can be referred to as a channel release process. At this interim processing step, the spaces between semiconductor layers 102 and 202 may be filled with ambient environment conditions (e.g., air, nitrogen, etc). In some embodiments, the semiconductor layers 102 and 202 can be referred to as nanosheets, nanowires, nanoslabs, nanorings having nano-scale size (e.g., a few nanometers), depending on their geometry. For example, in some embodiments the semiconductor layers 102 and 202 may be trimmed to have a substantial rounded shape (i.e., cylindrical) due to the selective etching process for completely removing the semiconductor layers 104 and 204. In that case, the resultant semiconductor layers 102 and 202 can be suspended and can be called nanowires. In embodiments in which the semiconductor layers 104 and 204 include, e.g., SiGe, and the semiconductor layers 102 and 202 include, e.g., Si or SiC, tetramethylammonium hydroxide (TMAH), ammonium hydroxide (NH₄OH) or the like may be used to remove the semiconductor layers 104 and 204.

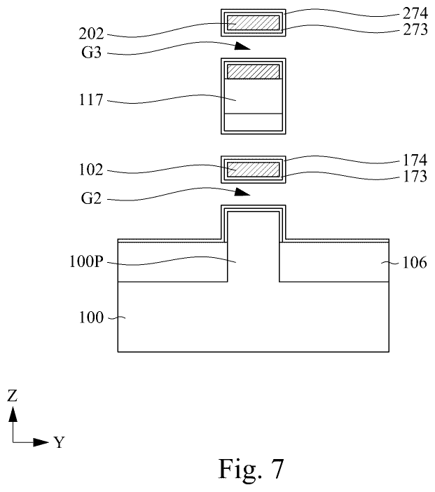

In FIG. 7, after the channel release process, gate dielectric layers 174 and 274 are formed wrapping around the semiconductor layers 102 and 202, respectively. In some embodiments, the gate dielectric layers 174 and 274 may be formed using a same deposition process. In some embodiments, interfacial layers 173, 273 may be formed over the semiconductor layers 102 and 202 prior to forming the gate dielectric layers 174 and 274. In some embodiments, the interfacial layer 173 is silicon oxide formed on exposed surfaces of semiconductor materials (e.g., Si) in the gate trenches GT1 by using, for example, thermal oxidation, chemical oxidation, wet oxidation or the like. As a result, surface portions of the semiconductor layers 102, 202 exposed in the gate trenches GT1 are oxidized into semiconductor oxide to form interfacial layers 173, 273. In some embodiments, the gate dielectric layers 174 and 274 have a dielectric constant greater than a dielectric constant of silicon oxide (about 3.9). The high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

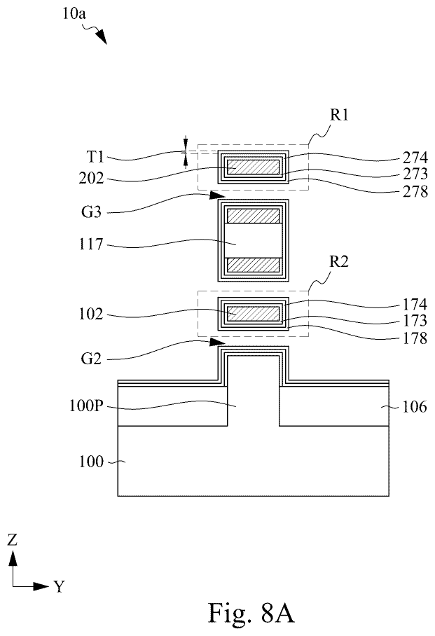

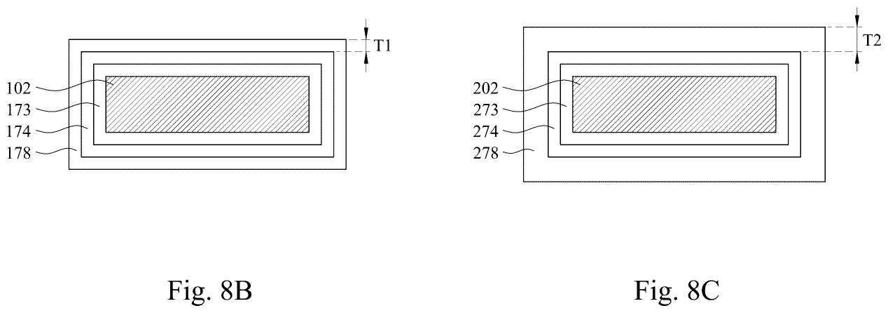

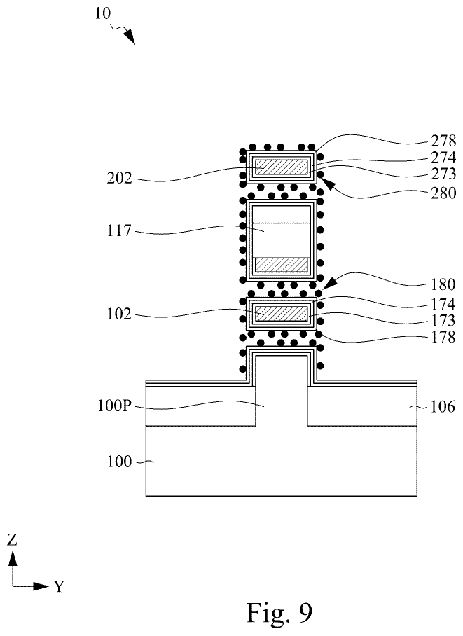

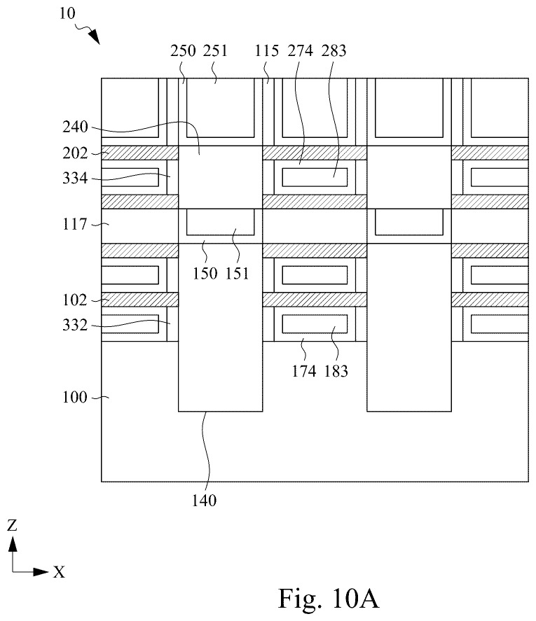

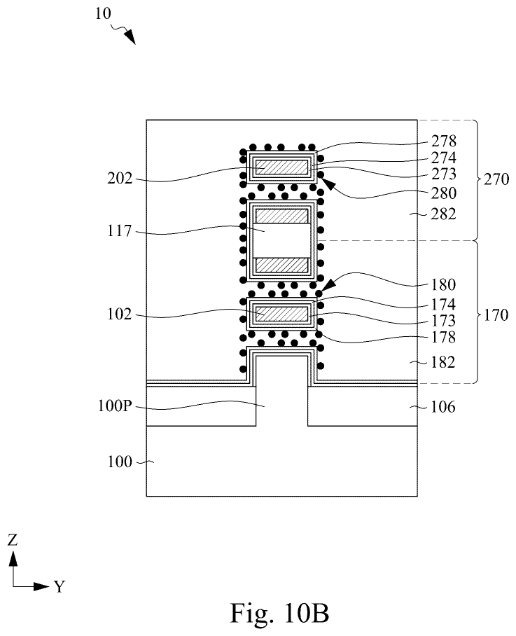

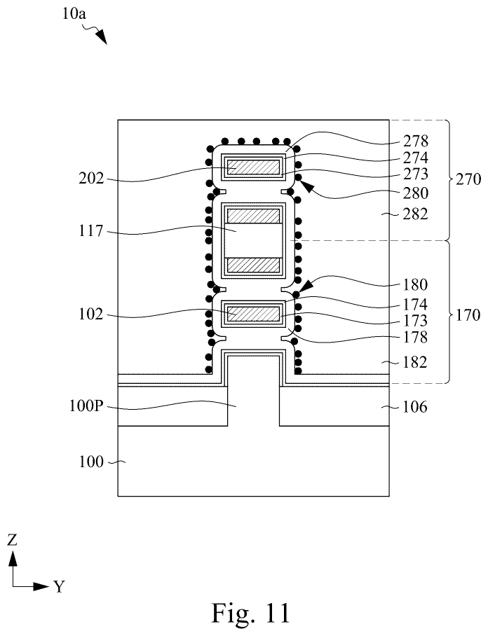

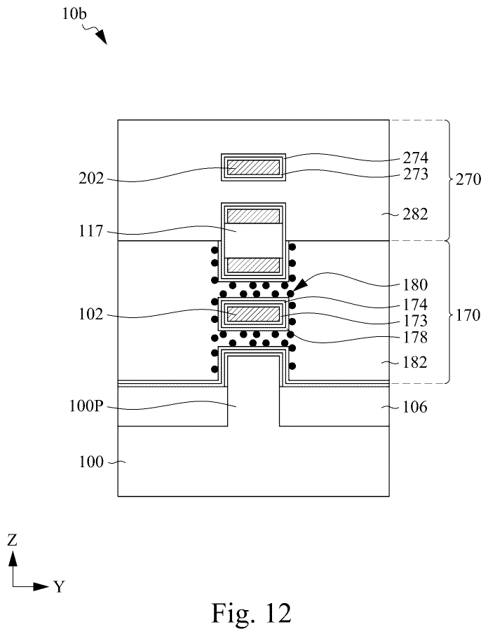

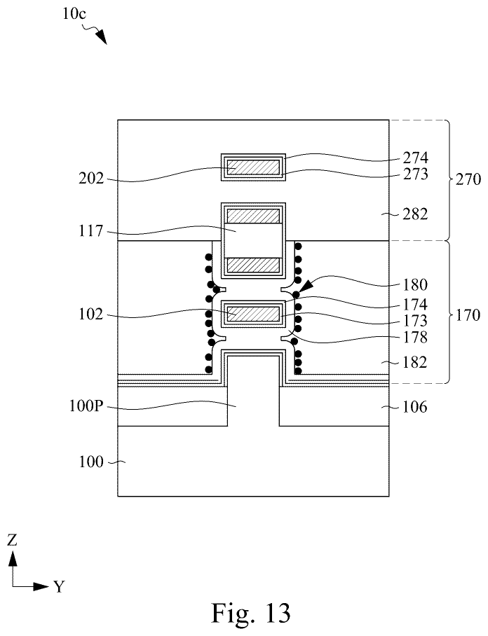

In FIG. 8A, conductive liners 178, 278 can be formed over the gate dielectric layers 174, 274, respectively. The conductive liners 178, 278 can act as a primary work function metal for the first metal gate structure 170 and the second metal gate structure 270 (see FIGS. 10A and 10B), respectively. FIGS. 8B and 8C are enlarged views of the regions R1 and R2 in FIG. 8B. Reference is made to FIGS. 8B and 8C. The conductive liner 178 can have a thickness T1 and the conductive liner 278 can have a thickness T2. The thickness T1 of the conductive liner 178 can influence the effective work function of the first metal gate structure 170 and the thickness T2 of conductive liner 278 can influence the effective work function of the second metal gate structure 270 (see FIGS. 10A-10B) since insertion positions of subsequently overlying conductive nanoparticles are determined thereby, which will be discussed in greater detail below. Therefore, the effective work functions of the first metal gate structure 170 and the second metal gate structure 270 can be controlled by the thicknesses T1 of conductive liners 178, 278, respectively. In some embodiments, the conductive liners 178 can be formed in the spaces G2 between corresponding two of the semiconductor layers 102 (also referred to as sheet-to-sheet spaces) and the conductive liners 278 can be formed in the spaces G3 between corresponding two of the semiconductor layers 202 (also referred to as sheet-to-sheet spaces). In some embodiments, the conductive liners 178, 278 can be formed by a suitable deposition method, such as ALD process. In some embodiments, the conductive liners 178, 278 interface with the gate dielectric layers 174 and 274, respectively. The conductive liners 178, 278 can include a work function metal such as a p-type work function metal (pWFM). For example, the pWFM layers can include a metallic material with a work function value equal to or greater than 4.5 eV (e.g., about 4.5 eV to about 5.5 eV), which can be closer to the valence band energy (e.g., 5.2 eV of Si or 4.8 eV of SiGe) than the conduction band energy (e.g., 4.1 eV of Si or 3.8 eV of SiGe) of Si-based or SiGe-based nanostructured channel regions, respectively. For example, the conductive liner 178 can be a metal nitride layer, such as a TiN layer. In some embodiments, a Ti-containing precursor and a nitrogen-containing precursor are reacted to form the TiN layer in the ALD process. For example, the Ti-containing precursor can include titanium chloride (TiCl₄), tetrakis (dimethylamino) titanium (TDMAT, (Ti(N(CH₃)₂)₄) or the like, and the nitrogen-containing precursor can include ammonia (NH₃). In some embodiments, the ALD process can be conducted at a temperature in a range from about 100° C. to about 600° C. and at a pressure in a range from about 0.1 torr to about 100 torr.

In FIG. 9, conductive nanoparticles 180, 280 can then be formed over the conductive liners 178, 278, respectively. For example, the conductive nanoparticles 180, 280 can include work function metal, such as a p-type work function metal. In some embodiments, the conductive nanoparticles 180, 280 include a material different from a material of the conductive liners 178, 278. That is, the conductive nanoparticles 180, 280 can include a work function different from a work function of the conductive liners 178, 278. In some embodiments, the conductive nanoparticles 180, 280 can include Ru-containing material, such as Ru with a diameter in a range from about 1 Å to about 5 Å such that the conductive nanoparticles 180, 280 can have small sizes, thus enabling the first metal gate structure 170 and the second metal gate structure 270 to thin down with low resistance. In FIG. 9, the conductive nanoparticles 180 can be arranged in rows along the Y-direction.

In some embodiments, the conductive nanoparticles 180, 280 can be formed by suitable nucleation process, such as ALD, CVD, or the like. In some embodiments, an Ru-containing precursor and a reactant are reacted to form the conductive nanoparticles 180, 280 in the nucleation process. For example, the Ru-containing precursor can include Ru₃(CO)₁₂ and the reactant can include CO. For example, the Ru-containing precursor can include Ru(CO)₃C₆H₈ and the reactant can include H₂. In some embodiments, the nucleation process can be conducted at a temperature in a range from about 100° C. to about 600° C. and at a pressure in a range from about 0.1 torr to about 100 torr. Deposition stops as long as Ru nucleation occurs, such that Ru is deposited as separated Ru nanoparticles at respective nucleation sites, not deposited as a continuous Ru layer. For example, the nucleation process refers to the initial formation of stable clusters or ‘seeds’ of the material (in this case, ruthenium) on the conductive liners 178, 278. If the conditions favor nucleation, Ru will start forming small isolated nanoparticles (that is, the conductive nanoparticles 180, 280) rather than a uniform film. When the surface energy of the formed clusters is lower than the energy required to add more atoms to an already existing layer, the material tends to favor the creation of separate nanoparticles. Adjusting the deposition parameters such as temperature, pressure, and the rate of Ru influx can help control whether nucleation predominates or if continuous layer growth occurs. For instance, maintaining a low substrate temperature while increasing the deposition rate can promote the formation of nanoparticles.

In some embodiments, after the nucleation process of the conductive nanoparticles 180, 280, an oxidation process can be performed to oxidize the conductive nanoparticles 180, forming conductive oxides. For example, the conductive oxides can include Ru-containing oxide, such as RuO₂ which has a work function greater than the work function of Ru. After the oxidation process, a thermal treatment may be performed to the conductive nanoparticles 180, 280 to transform the entire of the conductive nanoparticles 180, 280 into conductive oxides. Therefore, tunable effective work function with a wide range for the first metal gate structure 170 and the second metal gate structure 270 can be achieved by tuning the insertion positions of the conductive nanoparticles 180, 280 (that is, the thickness T1 of the conductive liners 178, 278) and the thermal treatment performed to the conductive nanoparticles 180, 280.

Further, tunable effective work function of the first metal gate structure 170 and the second metal gate structure 270 can be achieved by tuning a coverage rate of the conductive nanoparticles 180, 280. For example, by reducing the coverage rate in the nucleation process of the conductive nanoparticles 180, 280, a reduced number of conductive nanoparticles 180, 280 can be formed on the conductive liners 178, 278, respectively. In other words, the conductive nanoparticles 180, 280 may be spaced apart by an increased spacing from each other. In some embodiments, the conductive nanoparticles 180, 280 can be formed uniformly over the conductive liners 178, 278, respectively. That is, each of the conductive nanoparticles 180, 280 can be spaced apart by the substantially same spacing.

Reference is made to FIGS. 10A-10B. Then, conductive capping layers 182, 282 can be formed on the conductive nanoparticles 180, 280 in some embodiments. In some embodiments, the conductive capping layers 182, 282 can be formed by a suitable deposition method, such as ALD process. The conductive capping layers 182, 282 can include a work function metal such as a p-type work function metal. For example, the conductive capping layers 182, 282 can be a metal nitride layer, such as a TiN layer. Formation of the conductive capping layers 182, 282 can be similar to the formation of the conductive liners 178, 278, and thus the description thereof is omitted herein. The interfacial layer 173, 273, the conductive liners 178, 278, the conductive nanoparticles 180, 280, the conductive capping layers 182, 282 are omitted in FIG. 10A for illustration clarity.

In some embodiments, the formation of the conductive liners 178, 278, the conductive nanoparticles 180, 280 and the conductive capping layers 182, 282 may be performed in-situ. As used herein, the term “in-situ” is used to describe processes that are performed while a device or substrate remains within a processing system (e.g., including a load lock chamber, transfer chamber, processing chamber, or any other fluidly coupled chamber), and where for example, the processing system allows the substrate to remain under vacuum conditions. As such, the term “in-situ” may also generally be used to refer to processes in which the device or substrate being processed is not exposed to an external ambient (e.g., external to the processing system).

In some embodiments, a planarization process such as a chemical mechanical polish (CMP), an etch-back process, combinations thereof, or the like is utilized such that the top surfaces of the gate spacers 115, the second ILD 251, the second CESL 250 and the second metal gate structure 270 are substantially coplanar (within process variations). The conductive liner 278, the conductive nanoparticles 280 and the conductive capping layer 282 over the second ILD 251 can be referred to as a gate electrode 283 of the second metal gate structures 270. The conductive liner 178, the conductive nanoparticles 180 and the conductive capping layer 182 below the second ILD 251 can be referred to as a gate electrode 183 of the first metal gate structures 170. A target threshold voltage of the upper nanostructure-FETs and the lower nanostructure-FETs of the CFET 10 can be tuned effectively. In FIG. 9, the conductive nanoparticles 180, 280 can be distributed in distinct rectangular contour. The first metal gate structures 170 and the second metal gate structures 270 can include substantially the same work function and thus can be used as a single work function metal scheme.

FIG. 11 illustrates cross-sectional views of a CFET structure 10a in accordance with some embodiments of the present disclosure. The CFET structure 10a as illustrated in FIG. 11 is similar to that of FIGS. 10A-10B, except that the conductive nanoparticles 180 are not between two neighboring semiconductor layers 102 and the conductive nanoparticles 280 are not between two neighboring semiconductor layers 202. In FIG. 11, the conductive nanoparticles 180, 280 can be continuously distributed around outermost edges of the semiconductor layers 102, 202. For example, the conductive liners 178, 278 have an increased thickness and fill into sheet-to-sheet space (that is, the space between the semiconductor layers 102 and the space between the semiconductor layers 202), such as by increasing the deposition duration of the conductive liners 178, 278. The conductive nanoparticles 180 can then be formed over a surface of the conductive liners 178 and be absent between two neighboring semiconductor layers 102. Similarly, the conductive nanoparticles 280 can then be formed over a surface of the conductive liners 278 and be absent between two neighboring semiconductor layers 202.

FIG. 12 illustrates a cross-sectional view of a CFET structure 10b in accordance with some embodiments of the present disclosure. The CFET structure 10b as illustrated in FIG. 12 is similar to that of FIGS. 10A-10B, except that the conductive capping layer 282 of the second metal gate structure 270 can have a material different from a material of the conductive capping layer 182 of the first metal gate structure 170 such that the CFET structure 10b can be used as a dual work function metal scheme. For example, the conductive capping layer 282 of the second metal gate structure 270 can include TiAlC, and the conductive capping layer 182 of the first metal gate structure 170 can include TiN. The conductive nanoparticles 280 can be absent in the second metal gate structure 270. For example, after forming the structure in FIG. 10B, an etch process can be performed to the conductive capping layer 282, the conductive nanoparticles 280 and the conductive liners 278, exposing the gate dielectric layer 274. A deposition process can then be performed to form the conductive capping layer 282 including TiAlC over the gate dielectric layer 274 and the conductive capping layer 182. A planarization process such as a chemical mechanical polish (CMP), an etch-back process, combinations thereof, or the like can then be utilized to form the conductive capping layer 182 with a desired thickness.

FIG. 13 illustrates a cross-sectional view of a CFET structure 10c in accordance with some embodiments of the present disclosure. The CFET structure 10c as illustrated in FIG. 13 is similar to that of FIG. 12, except that the conductive nanoparticles 180 are not between two neighboring semiconductor layers 102 and the conductive nanoparticles 280 are not between two neighboring semiconductor layers 202. In FIG. 13, the conductive nanoparticles 180 can be continuously distributed around outermost edges of the semiconductor layers 102. For example, after forming the structure in FIG. 11, an etch process can be performed to the conductive capping layer 282, the conductive nanoparticles 280 and the conductive liners 278, exposing the gate dielectric layer 274. A deposition process can then be performed to form the conductive capping layer 282 including TiAlC over the gate dielectric layer 274 and the conductive capping layer 182. A planarization process such as a chemical mechanical polish (CMP), an etch-back process, combinations thereof, or the like can then be utilized to form the conductive capping layer 182 with a desired thickness.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that by forming the work function metal layers by inserting conductive nanoparticles in the work function metal layers, the work function can be tuned by controlling the coverage rate and the insertion position of the conductive nanoparticles and the thermal treatment performed to the conductive nanoparticles. Therefore, a target threshold voltage of the upper nanostructure-FETs and the lower nanostructure-FETs of the CFET can be tuned effectively. Another advantage is that such method of forming the work function metal layers can be used as a single work function metal scheme or dual work function metal scheme.

In some embodiments, a method of forming a semiconductor device comprises the following steps. A first semiconductor nanostructure is formed over a substrate. A second semiconductor nanostructure is formed over the first semiconductor nanostructure. A gate dielectric layer is formed surrounding the first semiconductor nanostructure. A gate electrode is formed over the gate dielectric layer, wherein forming the gate electrode comprises forming a conductive liner over the gate dielectric layer, and forming conductive nanoparticles over the conductive liner. In some embodiments, the conductive nanoparticles comprise an Ru-containing material. In some embodiments, the conductive nanoparticles comprise Ru, oxide of Ru, or a combination thereof. In some embodiments, the conductive nanoparticles comprise a p-type work function metal. In some embodiments, the conductive liner comprises TiN. In some embodiments, forming the gate electrode further comprises forming a conductive capping layer over the conductive nanoparticles. In some embodiments, conductive capping layer comprises a p-type work function metal. In some embodiments, the conductive capping layer comprises TiN.

In some embodiments, a method of forming a semiconductor device comprises the following step. A first channel region is formed over a substrate. A second channel region is formed over the first channel region. A first gate dielectric layer and a second gate dielectric layer are formed surrounding the first channel region and the second channel region, respectively. A first conductive liner and a second conductive liner are formed over the first gate dielectric layer and the second gate dielectric layer, respectively. First conductive nanoparticles are formed over the first conductive liner. In some embodiments, the first conductive nanoparticles have a work function different from a work function of the first conductive liner. In some embodiments, the first conductive nanoparticles have a work function greater than a work function of the first conductive liner. In some embodiments, the method further comprises forming a first conductive capping layer and a second conductive capping layer over the first conductive nanoparticles and the second conductive liner, respectively. In some embodiments, the first conductive capping layer comprises a work function different from a work function of the second conductive capping layer. In some embodiments, the first conductive nanoparticles are between two neighboring first semiconductor layers. In some embodiments, the first conductive nanoparticles are distributed in distinct rectangular contour. In some embodiments, the first conductive nanoparticles are continuously distributed around outermost edges of the first channel region. In some embodiments, the first conductive nanoparticles are arranged in rows.

In some embodiments, a semiconductor device comprises a substrate, channel layers over the substrate, a gate dielectric layer surrounding the channel layers, a gate electrode over the gate dielectric layer, wherein the gate electrode comprises a conductive liner, conductive nanoparticles over the conductive liner and a conductive capping layer over the conductive nanoparticles. In some embodiments, the conductive nanoparticles are between two neighboring semiconductor layers. In some embodiments, the conductive nanoparticles surround each of the channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a first semiconductor nanostructure over a substrate;
forming a second semiconductor nanostructure over the first semiconductor nanostructure;
forming a gate dielectric layer surrounding the first semiconductor nanostructure;
forming a gate electrode over the gate dielectric layer, wherein forming the gate electrode comprises:
forming a conductive liner over the gate dielectric layer; and
forming conductive nanoparticles over the conductive liner.

2. The method of claim 1, wherein the conductive nanoparticles comprise an Ru-containing material.

3. The method of claim 1, wherein the conductive nanoparticles comprise Ru, oxide of Ru, or a combination thereof.

4. The method of claim 1, wherein the conductive nanoparticles comprise a p-type work function metal.

5. The method of claim 1, wherein the conductive liner comprises TiN.

6. The method of claim 1, wherein forming the gate electrode further comprises:
forming a conductive capping layer over the conductive nanoparticles.

7. The method of claim 6, wherein conductive capping layer comprises a p-type work function metal.

8. The method of claim 6, wherein the conductive capping layer comprises TiN.

9. A method of forming a semiconductor device, comprising:
forming a first channel region over a substrate;
forming a second channel region over the first channel region;
forming a first gate dielectric layer and a second gate dielectric layer surrounding the first channel region and the second channel region, respectively;
forming a first conductive liner and a second conductive liner over the first gate dielectric layer and the second gate dielectric layer, respectively; and
forming first conductive nanoparticles over the first conductive liner.

10. The method of claim 9, wherein the first conductive nanoparticles have a work function different from a work function of the first conductive liner.

11. The method of claim 9, wherein the first conductive nanoparticles have a work function greater than a work function of the first conductive liner.

12. The method of claim 9, further comprising:
forming a first conductive capping layer and a second conductive capping layer over the first conductive nanoparticles and the second conductive liner, respectively.

13. The method of claim 12, wherein the first conductive capping layer comprises a work function different from a work function of the second conductive capping layer.

14. The method of claim 12, wherein the first conductive nanoparticles are between two neighboring first semiconductor layers.

15. The method of claim 12, wherein the first conductive nanoparticles are distributed in distinct rectangular contour.

16. The method of claim 12, wherein the first conductive nanoparticles are continuously distributed around outermost edges of the first channel region.

17. The method of claim 12, wherein the first conductive nanoparticles are arranged in rows.

18. A semiconductor device, comprising:
a substrate;
channel layers over the substrate;
a gate dielectric layer surrounding the channel layers;
a gate electrode over the gate dielectric layer, wherein the gate electrode comprises:
a conductive liner;
conductive nanoparticles over the conductive liner; and
a conductive capping layer over the conductive nanoparticles.

19. The semiconductor device of claim 18, wherein the conductive nanoparticles are between two neighboring semiconductor layers.

20. The semiconductor device of claim 18, wherein the conductive nanoparticles surround each of the channel layers.
